(19) United States
(12) Patent Application Publication
(10) Pub. No.: US 2019/0287444 A1
(43) Pub. Date: Sep. 19, 2019

(54) DISPLAY PANEL

(71) Applicant: Au Optronics Corporation, Hsinchu (TW)

(72) Inventors: Chun-Da Tu, Hsinchu City (TW); Ming-Hsien Lee, Hsinchu City (TW); Yi-Cheng Lin, New Taipei City (TW); Kai-Wei Hong, Hsinchu (TW); Chuang-Cheng Yang, Changhua County (TW); Chun-Feng Lin, Taichung City (TW)

(73) Assignee: Au Optronics Corporation, Hsinchu (TW)

(21) Appl. No.: 16/055,144

(22) Filed: Aug. 5, 2018

(30) Foreign Application Priority Data
Mar. 19, 2018 (TW) 107109349

(51) Int. Cl. G09G 3/20; G11C 19/28

(52) U.S. Cl. CPC G09G 3/20; G11C 19/287; G09G 2310/0286; G09G 2310/08; G09G 2310/0251; G09G 2300/0439; G09G 2330/02

(57) ABSTRACT

A display panel including a pixel array, a plurality of first shift registers, a plurality of second shift registers, a plurality of first discharge circuits, and a plurality of second discharge circuits is provided. The pixel array includes a plurality of gate lines. The shift registers provide a plurality of gate signals to the gate lines. Each of the first discharge circuits receives a third gate signal to discharge a same first gate line together with the corresponding first shift register. A rising edge of the third gate signal substantially matches a falling edge of the corresponding first gate signal. Each of the second discharge circuits receives a fourth gate signal to discharge a same second gate line together with the corresponding second shift register. A rising edge of the fourth gate signal substantially matches a falling edge of the corresponding second gate signal.

### CROSS-REFERENCE TO RELATED APPLICATION

This application claims the priority benefit of Taiwan application serial no. 107109349, filed on Mar. 19, 2018. The entirety of the above-mentioned patent application is hereby incorporated by reference herein and made a part of this specification.

### BACKGROUND

### Technical Field

The disclosure relates to a display apparatus. More particularly, the disclosure relates to a display panel.

### Description of Related Art

As the electronic technology advances, display apparatuses have become indispensable in our daily lives. In order to provide a favorable human-machine interface, high-quality display panels are necessary in display apparatuses.

As the resolution of the display panels continues to advance, a gate driving circuit adopting the interlace driving structure is used by a designer most of the time to be disposed in a display panel, so as to reduce the layout area of the gate driving circuit and to further reduce the border of the display panel. Nevertheless, the pull-down speed of the gate driving signal is affected under such design, meaning that the falling time of the gate driving signal during discharging increases. In this case, overall driving time of the display panel is prolonged, and consequently, quality of the display screen is lowered. Therefore, how a gate driving circuit having sufficient discharging capability and reduced layout area can be designed is one of the important issues to be addressed by those skilled in the art.

### SUMMARY

The disclosure provides a display panel in which a falling time of a gate signal is shortened during discharging as such overall driving time of the display panel is reduced and quality of a display screen presented by the display panel is further enhanced.

In an embodiment of the disclosure, a display panel includes a pixel array, a plurality of first shift registers, a plurality of second shift registers, a plurality of first discharge circuits, and a plurality of second discharge circuits. The pixel array includes a plurality of gate lines. The first shift registers are coupled to first terminals of a plurality of first gate lines of the gate lines for providing a plurality of first gate signals to the first gate lines. The second shift registers are coupled to first terminals of a plurality of second gate lines of the gate lines for providing a plurality of second gate signals to the second gate lines. The first discharge circuits are coupled to second terminals of the first gate lines, and each of the first discharge circuits receives a third gate signal to discharge a same first gate line together with the corresponding first shift register. A rising edge of the third gate signal substantially matches a falling edge of the first gate signal provided by the corresponding first shift register. The second discharge circuits are coupled to second terminals of the second gate lines, and each of the second discharge circuits receives a fourth gate signal to discharge a same second gate line together with the corresponding second shift register. A rising edge of the fourth gate signal substantially matches a falling edge of the second gate signal provided by the corresponding second shift register.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a display panel according to an embodiment of the disclosure.

FIG. 2 is a schematic diagram of waveforms of a display panel according to an embodiment of the disclosure.

FIG. 3 is a schematic diagram illustrating shift registers and discharge circuits in a display panel according to an embodiment of the disclosure.

FIG. 4 is a circuit diagram of a shift register and a discharge circuit at a first side according to another embodiment of the disclosure.

### DESCRIPTION OF THE EMBODIMENTS

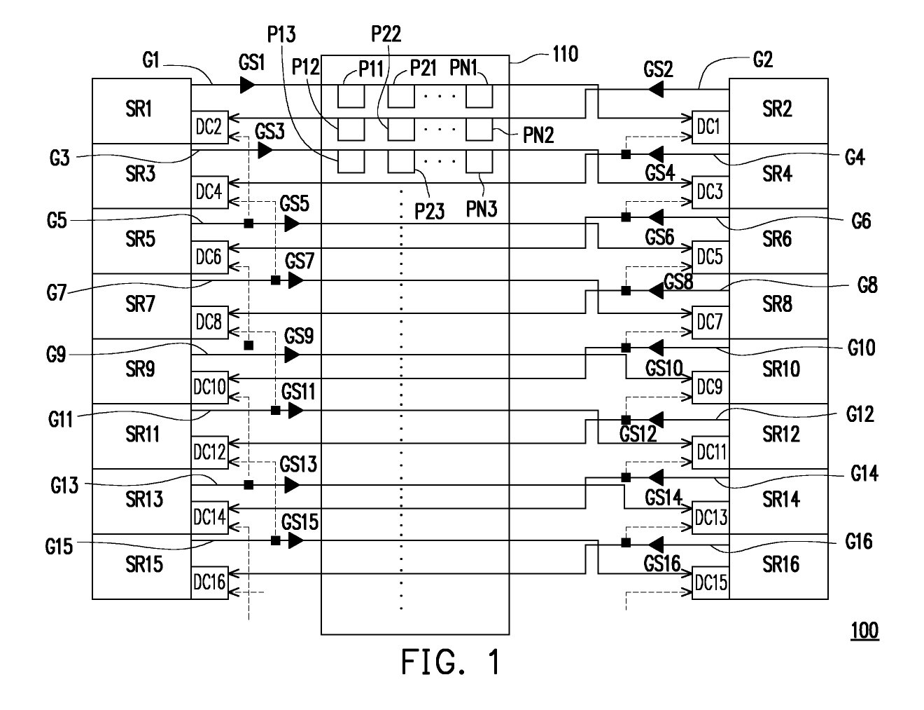

FIG. 1 is a schematic diagram of a display panel 100 according to an embodiment of the disclosure. With reference to FIG. 1, in this embodiment, the display panel 100 includes a pixel array 110, a plurality of first shift registers (e.g., odd-numbered shift registers such as a shift register SR1 and shift registers SR3 to SR15), a plurality of second shift registers (e.g., even-numbered shift registers such as a shift register SR2 and shift registers SR4 to SR16), a plurality of first discharge circuits (e.g., odd-numbered discharge circuits such as a discharge circuit DC1 and discharge circuits DC3 to DC 15), and a plurality of second discharge circuits (e.g., even-numbered discharge circuits such as a discharge circuit DC2 and discharge circuits DC4 to DC16).

A plurality of pixels (e.g., pixels P11 to PN1, pixels P12 to PN2, pixels P13 to PN3) and a plurality of gate lines G1 to G16 are included in the pixel array 110. Note that the pixels P11 to PN1, P12 to PN2, and P13 to PN3 are arranged in a matrix and are disposed at a crossover region where data lines (not shown) intersect gate lines G1 to G16, so as to control circuit operation of the pixel array (e.g., the pixel array 110) through the corresponding gate lines G1 to G16 and the data lines (not shown). In the embodiments of the disclosure, numbers of the pixels, the gate lines, the discharge circuits, and the shift registers in the pixel array 110 can be determined by people having ordinary skill in the art according to design requirement of the display panel 100, and the disclosure is not limited to the numbers listed above. Further, N is a positive integer. For ease of description, in the embodiment, only the gate lines G1 to G16 and the pixels P11 to PN1, P12 to PN2, and P13 to PN3 are depicted in FIG. 1, but the disclosure is not limited herein.

In this embodiment, the first shift registers (e.g., the shift register SR1, the shift register SR3, . . . , and the shift register SR15) are respectively coupled to first terminals of a plurality of first gate lines (e.g., the odd-numbered gate lines such as the gate line G1 and the gate lines G3 to G15) of the gate lines G1 to G16. Further, the first shift registers (e.g., the shift register SR1 and the shift register SR3 to SR15) respectively provide a plurality of first gate signals (e.g., odd-numbered gate signals such as a gate signal GS1 and gate signals GS3 to GS15) to the first gate lines (e.g., the gate line G1, the gate line G3, . . . , and the gate line G15). For instance, the shift register SR1 is coupled to the first terminal of the gate line G1, and the shift register SR1 provide the gate signal GS1 to the gate line Gl. The shift register SR3 is coupled to the first terminal of the gate line G3, the shift register SR3 provide the gate signal GS3 to the gate line G3, and the rest is deduced by analogy.

In another aspect, the second shift registers (e.g., the shift register SR2, the shift register SR4, . . . , and the shift register SR16) are respectively coupled to first terminals of a plurality of second gate lines (e.g., the even-numbered gate lines such as the gate line G2 and the gate lines G4 to G16) of the gate lines G1 to G16. Further, the second shift registers (e.g., the shift register SR2, the shift register SR4, . . . , and the shift register SR16) respectively provide a plurality of second gate signals (e.g., even-numbered gate signals such as a gate signal GS2 and gate signals GS4 to GS16) to the second gate lines (e.g., the gate line G2, the gate line G4, . . . , and the gate line G16). For instance, the shift register SR2 is coupled to the first terminal of the gate line G2, and the shift register SR2 provide the gate signal GS2 to the gate line G2. The shift register SR4 is coupled to the first terminal of the gate line G4, the shift register SR4 provide the gate signal GS4 to the gate lines G2, and the rest is deduced by analogy.

In this embodiment, the first gate lines are exemplified by being the odd-numbered gate lines (e.g., the gate line G1, the gate line G3, . . . , and the gate line G15), and the second gate lines are exemplified by being the even-numbered gate lines (e.g., the gate line G2, the gate line G4, . . . , and the gate line G16), but the embodiments of the disclosure are not limited herein.

In this embodiment, the first discharge circuits (e.g., the discharge circuit DC1, the discharge circuit DC3, . . . , and the discharge circuit DC15) are respectively coupled to second terminals of the first gate lines (e.g., the gate line G1, the gate line G3, . . . , and the gate line G15). Further, the first discharge circuits (e.g., the discharge circuit DC1, the discharge circuit DC3, . . . , and the discharge circuit DC15) respectively receive third gate signals (e.g., the even-numbered gate signals such as the gate signal GS4 and the gate signals GS6 to GS16). For instance, the discharge circuit DC1 is coupled to the second terminal of the gate line G1, and the discharge circuit DC1 receive the gate signal GS4 provided by the shift register SR4. In addition, the discharge circuit DC3 is coupled to the second terminal of the gate line G3, the discharge circuit DC3 receive the gate signal GS6 provided by the shift register SR6, and the rest is deduced by analogy.

In this embodiment, the second discharge circuits (e.g., the discharge circuit DC2, the discharge circuit DC4, . . . , and the discharge circuit DC16) are respectively coupled to second terminals of the second gate lines (e.g., the gate line G2, the gate line G4, . . . , and the gate line G16). Further, the second discharge circuits (e.g., the discharge circuit DC2, the discharge circuit DC4, . . . , and the discharge circuit DC16) respectively receive fourth gate signals (e.g., the odd-numbered gate signals such as the gate signal GS3 and the gate signals GS5 to GS15). For instance, the discharge circuit DC2 is coupled to the second terminal of the gate line G2, and the discharge circuit DC2 receive the gate signal GS5 provided by the shift register SR5. In addition, the discharge circuit DC4 is coupled to the second terminal of the gate line G4, the discharge circuit DC4 receive the gate signal GS7 provided by the shift register SR7, and the rest is deduced by analogy.

As shown in FIG. 1, the first shift registers (e.g., the shift register SR1 and the shift registers SR3 to SR15) and the second discharge circuits (e.g., the discharge circuit DC2, the discharge circuit DC4, . . . , and the discharge circuit DC16) are disposed at a first side of the pixel array 110 (e.g., a left side of the pixel array 110). Further, the second shift registers (e.g., the shift register SR2, the shift register SR4, . . . , and the shift register SR16) and the first discharge circuits (e.g., the discharge circuit DC1, the discharge circuit DC3, . . . , and the discharge circuit DC15) are disposed at a second side of the pixel array 110 (e.g., a right side of the pixel array 110) opposite to the first side, but the disclosure is not limited herein.

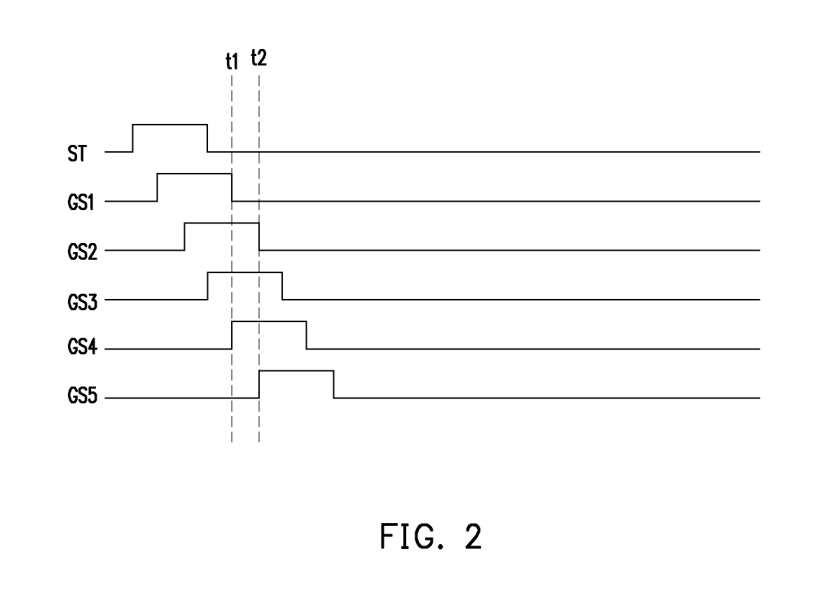

FIG. 2 is a schematic diagram of waveforms of the display panel 100 according to an embodiment of the disclosure. With reference to FIG. 1 and FIG. 2 together, in this embodiment, when a startup signal ST is enabled (e.g., at a high voltage level), the shift registers SR1 to SR16 provide the enabled gate signals GS1 to GS16 in sequence. Further, the shift registers SR1 to SR16 and the discharge circuits DC1 to DC16 are operated simultaneously. Hence, one of the shift registers SR1 to SR16 and the corresponding discharge circuit (e.g., DC1 to DC16) simultaneously pull down a voltage of a same gate line (e.g., G1 to G16). As such, falling edges of the gate signals GS1 to GS16 are correspondingly formed, and falling time required by the gate signals GS1 to GS16 is reduced.

For instance, taking the gate signals GS1 to GS5 for example, the shift register SR1 coupled to the gate line G1 and the discharge circuit DC1 are operated simultaneously in this embodiment. In other words, when the discharge circuit DC1 receives the enabled gate signal GS4 provided by the shift register SR4, the discharge circuit DC1 and the corresponding shift register SR1 discharge the gate line G1, as shown by a time point t1. Among them, a rising edge of the gate signal GS4 substantially matches the falling edge of the gate signal GS1 provided by the corresponding shift register SR1.

In another aspect, when the discharge circuit DC2 receives the enabled gate signal GS5 provided by the shift register SR5, the discharge circuit DC2 and the corresponding shift register SR2 discharge the gate line G2, as shown by a time point t2. Among them, a rising edge of the gate signal GS5 substantially matches the falling edge of the gate signal GS2 provided by the corresponding shift register SR2.

Specifically, in this embodiment, when the gate signal (the gate signals GS1 to GS16) of each of the gate lines (e.g., the gate lines G1 to G16) performs discharging, the second discharge circuits (e.g., the discharge circuit DC2, the discharge circuit DC4, . . . , and the discharge circuit DC16) and the first discharge circuits (e.g., the discharge circuit DC1, the discharge circuit DC3, . . . , and the discharge circuit DC15) disposed at the first side and the second side of the pixel array 110 together with the corresponding shift registers SR1 to SR16 discharge the same gate lines G1 to G16 in this embodiment. As such, when the gate signals GS1 to GS16 perform discharging, capability of pulling down the gate signals GS1 to GS16 from a high voltage level to a low voltage level is enhanced, and that discharging time of the gate signals GS1 to GS16 can be shortened. Overall delay time when the display panel 100 works is further reduced, as such, quality of the display screen is improved.

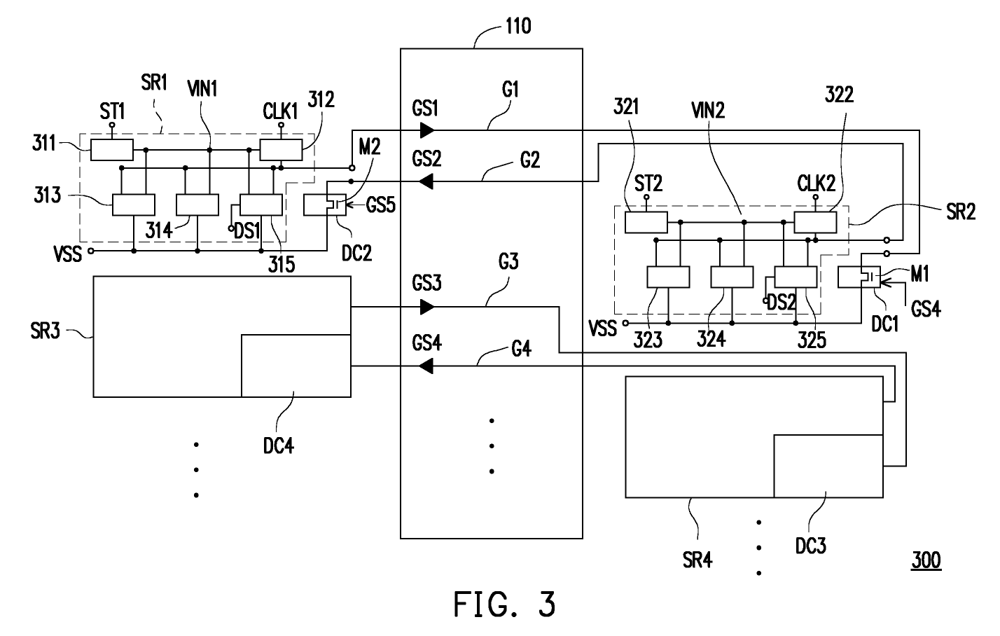

FIG. 3 is a schematic diagram illustrating shift registers and discharge circuits in a display panel according to an embodiment of the disclosure. With reference to FIG. 1 and FIG. 3 together, a display panel 300 is approximately similar to the display panel 100, wherein identical or similar components are assigned with identical or similar reference numerals. In FIG. 3, for ease of description, the shift register SR1 and the shift register SR2 are used to respectively explain circuit structures of the first shift register and the second shift register located at the first side and the second side of the pixel array 110. Further, the discharge circuit DC1 and the discharge circuit DC2 are used to respectively explain circuit structures of the first discharge circuit and the second discharge circuit located at the second side and the first side of the pixel array 110, and operational relations between the rest of the shift registers and the discharge circuits are deduced by analogy.

Specifically, at the first side of the pixel array 110 (e.g., the left side of the pixel array 110), the shift register SR1 (corresponding to the first shift register) includes a charging circuit 311 (corresponding to a first charging circuit), a pull-up circuit 312 (corresponding to a first pull-up circuit), a voltage regulator circuit 313 and a voltage regulator circuit 314 (corresponding to a first voltage regulator circuit and a second voltage regulator circuit), and a pull-down circuit 315 (corresponding to a first pull-down circuit).

In terms of the details of operation of the shift register SR1, to be specific, the charging circuit 311 receives a startup signal ST1 and charges an internal voltage VIN1 (corresponding to a first internal voltage). Note that the pull-up circuit 312 receives the internal voltage VIN1 and a clock signal CLK1 (corresponding to a first clock signal). Moreover, the pull-up circuit 312 pulls up the corresponding first gate signal (e.g., the gate signal GS1) according to states of the internal voltage VIN1 and the clock signal CLK1. For instance, in the shift register SR1, when the startup signal ST1 is configured to be enabled (e.g., at the high voltage level), the charging circuit 311 charges the internal voltage VIN1. At this time, the pull-up circuit 312 pulls up the corresponding gate signal GS1 according to states of the internal voltage VIN1 and the clock signal CLK1, as such, charging performed by the gate signal GS1 is completed.

In another aspect, the voltage regulator circuit 313 and the voltage regulator circuit 314 of this embodiment both receive the internal voltage VIN1. Moreover, the voltage regulator circuit 313 and the voltage regulator circuit 314 performs voltage regulation to the first gate signal (e.g., the gate signal GS1) according to the state of the internal voltage VIN1. Among them, the voltage regulator circuit 313 and the voltage regulator circuit 314 of this embodiment is operated alternately. In addition, the pull-down circuit 315 of this embodiment receive a pull-down signal DS1 (corresponding to a first pull-down signal). Moreover, the pull-down circuit 315 pulls down the corresponding first gate signal (e.g., the gate signal GS1) according to a state of the pull-down signal DS1. For instance, in the shift register SR1, when the gate signal GS1 is about to perform discharging, the pull-down circuit 315 pulls down the corresponding gate signal GS1 according to the pull-down signal DS1, as such, discharging performed by the gate signal GS1 is completed.

In addition, at the first side of the pixel array 110 (e.g., the left side of the pixel array 110), the discharge circuit DC2 (corresponding to the second discharge circuit) includes a transistor M2 (corresponding to a second transistor). To be specific, a source (corresponding to the first terminal) of the transistor M2 is coupled to the second terminal of the corresponding second gate line (e.g., the gate line G2), a gate (corresponding to a control terminal) of the transistor M2 receives the fourth gate signal (e.g., the gate signal GS5), and a drain (corresponding to the second terminal) of the transistor M2 receives a system low voltage VSS.

In another aspect, at the second side of the pixel array 110 (e.g., the right side of the pixel array 110), the shift register SR2 (corresponding to the second shift register) includes a charging circuit 321 (corresponding to a second charging circuit), a pull-up circuit 322 (corresponding to a second pull-up circuit), the voltage regulator circuit 323 and the voltage regulator circuit 324 (corresponding to a third voltage regulator circuit and a fourth voltage regulator circuit), and a pull-down circuit 325 (corresponding to a second pull-down circuit).

In terms of operational details of the shift register SR2, to be specific, the charging circuit 321 receives a startup signal ST2 and charges an internal voltage VIN2 (corresponding to the second internal voltage). Note that the pull-up circuit 322 receives the internal voltage VIN2 and a clock signal CLK2 (corresponding to a second clock signal). Moreover, the pull-up circuit 322 pulls up the corresponding second gate signal (e.g., the gate signal GS2) according to states of the internal voltage VIN2 and the clock signal CLK2. For instance, in the shift register SR2, when the startup signal ST2 is configured to be enabled (e.g., at the high voltage level), the charging circuit 321 charges the internal voltage VIN2. At this time, the pull-up circuit 322 pulls up the corresponding gate signal GS2 according to the states of the internal voltage VIN2 and the clock signal CLK2, as such, charging performed by the gate signal GS2 is completed.

In another aspect, the voltage regulator circuit 323 and the voltage regulator circuit 324 both receive the internal voltage VIN2. Moreover, the voltage regulator circuit 323 and the voltage regulator circuit 324 performs voltage regulation to the second gate signal (e.g., the gate signal GS2) according to the state of the internal voltage VIN2. Among them, the voltage regulator circuit 323 and the voltage regulator circuit 324 of this embodiment is operated alternately. In addition, the pull-down circuit 325 of this embodiment receive a pull-down signal DS2 (corresponding to a second pull-down signal). Moreover, the pull-down circuit 325 pulls down the corresponding second gate signal (e.g., the gate signal GS2) according a state of the pull-down signal DS2. For instance, in the shift register SR2, when the gate signal GS2 performs discharging, the pull-down circuit 325 pulls down the corresponding gate signal GS2 according to the pull-down signal DS2, as such, discharging performed by the gate signal GS2 is completed.

In addition, at the second side of the pixel array 110 (e.g., the right side of the pixel array 110), the discharge circuit DC1 (corresponding to the first discharge circuit) includes a transistor M1 (corresponding to a first transistor). To be specific, a source (corresponding to the first terminal) of the transistor M1 is coupled to the second terminal of the corresponding first gate line (e.g., the gate line G1), a gate (corresponding to the control terminal) of the transistor M1 receives the third gate signal (e.g., the gate signal GS4), and a drain (corresponding to the second terminal) of the transistor M1 receives the system low voltage VSS.

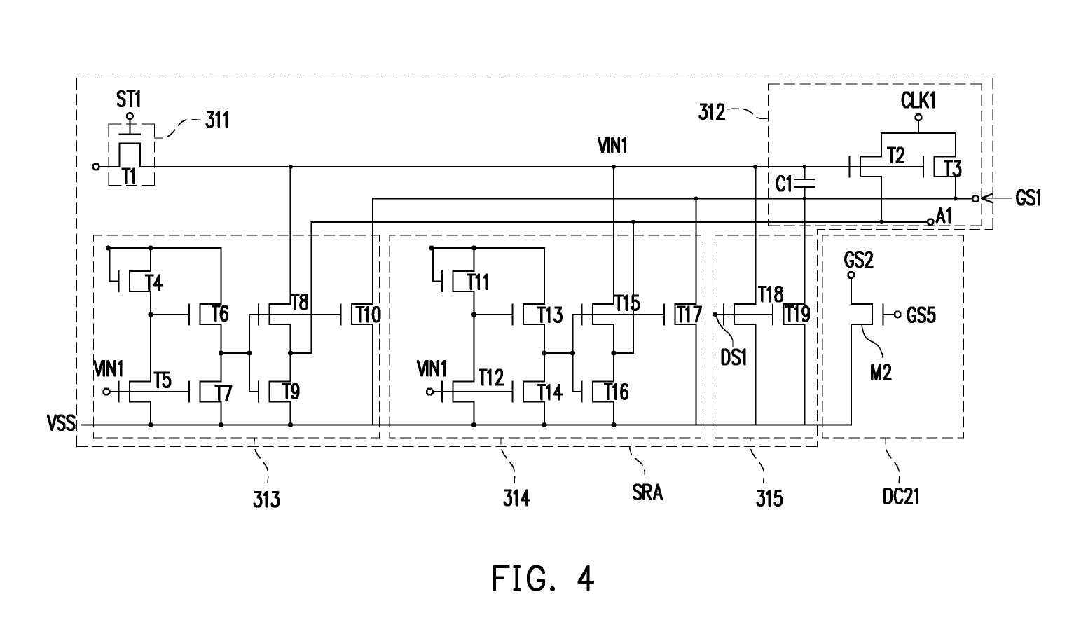

FIG. 4 is a circuit diagram of a shift register and a discharge circuit at a first side according to another embodiment of the disclosure. With reference to FIG. 3 and FIG. 4 together, a shift register SRA and a discharge circuit DC21 are approximately similar to the shift register SR1 and the discharge circuit DC2 respectively, and a difference therebetween includes that the pull-up circuit 312 (corresponding to the first pull-up circuit) further receive a driving signal A1 (corresponding to a first driving signal), wherein identical or similar components are assigned with identical or similar reference numerals. Specifically, in this embodiment, the shift register SRA (corresponding to the first shift register) includes the charging circuit 311 (corresponding to the first charging circuit), the pull-up circuit 312 (corresponding to the first pull-up circuit), the voltage regulator circuit 313 and the voltage regulator circuit 314 (corresponding to the first voltage regulator circuit and the second voltage regulator circuit), and the pull-down circuit 315 (corresponding to the first pull-down circuit).

To be specific, in the charging circuit 311 of this embodiment, a transistor T1 includes a first terminal receiving the internal voltage VIN1, a control terminal receiving the startup signal ST1, and a second terminal receiving the gate signal. In another aspect, a transistor T2 in the pull-up circuit 312 includes a first terminal receiving the clock signal CLK1, a control terminal receiving the internal voltage VIN1, and a second terminal receiving the driving signal A1. A transistor T3 in the pull-up circuit 312 includes a first terminal receiving the clock signal CLK1, a control terminal receiving the internal voltage VIN1, and a second terminal coupled to a second terminal of a capacitor C1. The capacitor Cl in the pull-up circuit 312 includes a first terminal and the second terminal, wherein the first terminal of the capacitor C1 receives the internal voltage VIN1, and the second terminal of the capacitor C1 receives the gate signal GS1.

In another aspect, in the voltage regulator circuit 313 of this embodiment, a first terminal and a control terminal of a transistor T4 are coupled to each other, and the transistor T4 includes a second terminal coupled to a first terminal of a transistor T5. The transistor T5 includes the first terminal coupled to the second terminal of the transistor T4, a control terminal receiving the internal voltage VIN1, and a second terminal receiving the system low voltage VSS. A transistor T6 includes a first terminal coupled to the first terminal of the transistor T4, a control terminal coupled to the second terminal of the transistor T4, and a second terminal coupled to a first terminal of a transistor T7. The transistor T7 includes the first terminal coupled to the second terminal of the transistor T6, a control terminal receiving the internal voltage VIN1, and a second terminal receiving the system low voltage VSS. A transistor T8 includes a first terminal receiving the internal voltage VIN1, a control terminal coupled to the second terminal of the transistor T6, and a second terminal coupled to a first terminal of a transistor T9. The transistor T9 includes the first terminal coupled to the second terminal of the transistor T8, a control terminal coupled to the second terminal of the transistor T6, and a second terminal receiving the system low voltage VSS. The transistor T10 includes a first terminal coupled to the second terminal of the capacitor C1, a control terminal coupled to the second terminal of the transistor T6, and a second terminal receiving the system low voltage VSS.

In another aspect, in the voltage regulator circuit 314 of this embodiment, a first terminal and a control terminal of a transistor T11 are coupled to each other, and the transistor T11 includes a second terminal coupled to a first terminal of a transistor T12. The transistor T12 includes the first terminal coupled to the second terminal of the transistor T11, a control terminal receiving the internal voltage VIN1, and a second terminal receiving the system low voltage VSS. A transistor T13 includes a first terminal coupled to the first terminal of the transistor T11, a control terminal coupled to the second terminal of the transistor T11, and a second terminal coupled to a first terminal of a transistor T14. The transistor T14 includes the first terminal coupled to the second terminal of the transistor T13, a control terminal receiving the internal voltage VIN1, and a second terminal receiving the system low voltage VSS. A transistor T15 includes a first terminal receiving the internal voltage VIN1, a control terminal coupled to the second terminal of the transistor T13, and a second terminal coupled to a first terminal of a transistor T16. The transistor T16 includes the first terminal coupled to the second terminal of the transistor T15, a control terminal coupled to the second terminal of the transistor T13, and a second terminal receiving the system low voltage VSS. A transistor T17 includes a first terminal coupled to the second terminal of the capacitor C1, a control terminal coupled to the second terminal of the transistor T13, and a second terminal receiving the system low voltage VSS.

In another aspect, in the pull-down circuit 315 of this embodiment, a transistor T18 includes a first terminal receiving the internal voltage VIN1, a control terminal receiving the pull-down signal DS1, and a second terminal receiving the system low voltage VSS. A transistor T19 includes a first terminal coupled to the second terminal of the capacitor C1, a control terminal receiving the pull-down signal DS1, and a second terminal receiving the system low voltage VSS. Note that in the discharge circuit DC21 of this embodiment, the transistor M2 includes the first terminal receiving the gate signal GS2, the control terminal receiving the gate signal GS5, and the second terminal receiving the system low voltage VSS.

Different from the shift register SR1 of the foregoing embodiment, the pull-up circuit 312 (corresponding to the first pull-up circuit) in the shift register SRA in this embodiment pulls up the corresponding driving signal A1 (corresponding to the first driving signal) of a plurality of first driving signals according to the internal voltage VIN1 (corresponding to the first internal voltage) and the clock signal CLK1 (corresponding to the first clock signal). In addition, the pull-down circuit 315 (corresponding to the first pull-down circuit) of this embodiment pulls down the corresponding driving signal A1 according to the pull-down signal DS1 (corresponding to the first pull-down signal). Moreover, a falling edge of the first gate signal of this embodiment substantially matches a falling edge of the clock signal CLK1.

Note that the shift register SR2 (corresponding to the second shift register) and an internal circuit of the discharge circuit DC1 (corresponding to the first discharge circuit) in FIG. 3 respectively are identical to or similar to the shift register SRA and an internal circuit of the discharge circuit DC21 in FIG. 4. In other words, people having ordinary skill in the art can respectively implement the shift register SR2 (corresponding to the second shift register) and the internal circuit of the discharge circuit DC1 (corresponding to the first discharge circuit) in FIG. 3 according to the shift register SRA and the internal circuit of the discharge circuit DC21 in FIG. 4, and a relevant description thereof is thus omitted.

In view of the foregoing, in the display panel provided by the embodiments of the disclosure, plural first discharge circuits are disposed at the second side of the pixel array for receiving the third gate signals, so as to discharge the same first gate lines together with the corresponding first shift registers. Hence, the rising edges of the third gate signals substantially match the falling edges of the first gate signals provided by the corresponding first shift registers. In addition, in the display panel, plural second discharge circuits are also disposed at the first side of the pixel array opposite to the second side for receiving the fourth gate signals, so as to discharge the same second gate lines together with the corresponding second shift registers. Hence, the rising edges of the fourth gate signals substantially match the falling edges of the second gate signals provided by the corresponding second shift registers. In this way, in the display panel provided by the embodiments of the disclosure, discharging capability of pulling down the gate signals from the high voltage level to the low voltage level is enhanced, and the layout area is saved. Therefore, quality of the display screen is improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display panel, comprising:
a pixel array, having a plurality of gate lines, wherein the plurality of gate lines have a plurality of first gate lines and a plurality of second gate lines;
a plurality of first shift registers, coupled to first terminals of the plurality of first gate lines, configured to generate a plurality of first gate signals to the first gate lines;
a plurality of second shift registers, coupled to first terminals of the plurality of second gate lines, configured to generate a plurality of second gate signals to the second gate lines;
a plurality of first discharge circuits, coupled to second terminals of the first gate lines, each of the first discharge circuits receiving a third gate signal to discharge a same first gate line together with the corresponding first shift register, wherein a rising edge of the third gate signal substantially matches a falling edge of the first gate signal provided by the corresponding first shift register; and
a plurality of second discharge circuits, coupled to second terminals of the second gate lines, each of the second discharge circuits receiving a fourth gate signal to discharge a same second gate line together with the corresponding second shift register, wherein a rising edge of the fourth gate signal substantially matches a falling edge of the second gate signal provided by the corresponding second shift register.

2. The display panel as claimed in claim 1, wherein each of the first discharge circuits comprises a first transistor having a first terminal, a second terminal, and a control terminal, wherein the first terminal is coupled to the second terminal of the corresponding first gate line, the control terminal receives the third gate signal, and the second terminal receives a system low voltage.

3. The display panel as claimed in claim 1, wherein each of the first shift registers comprises:
a first charging circuit, receiving a startup signal to charge a first internal voltage;
a first pull-up circuit, receiving the first internal voltage and a first clock signal for pulling up the corresponding first gate signal according to the first internal voltage and the first clock signal;
a first voltage regulator circuit and a second voltage regulator circuit, respectively receiving the first internal voltage for performing voltage regulation to the corresponding first gate signal according to the first internal voltage, wherein the first voltage regulator circuit and the second voltage regulator circuit operates alternately; and
a first pull-down circuit, receiving a first pull-down signal for pulling down the corresponding first gate signal according to the first pull-down signal.

4. The display panel as claimed in claim 3, wherein the first pull-up circuit further pulls up a corresponding first driving signal of a plurality of first driving signals according to the first internal voltage and the first clock signal.

5. The display panel as claimed in claim 4, wherein the first pull-down circuit further pulls down the corresponding first driving signal according to the first pull-down signal.

6. The display panel as claimed in claim 3, wherein the falling edge of the corresponding first gate signal substantially matches a falling edge of the first clock signal.

7. The display panel as claimed in claim 1, wherein each of the second discharge circuits comprises a second transistor having a first terminal, a second terminal, and a control terminal, wherein the first terminal is coupled to the second terminal of the corresponding second gate line, the control terminal receives the fourth gate signal, and the second terminal receives a system low voltage.

8. The display panel as claimed in claim 1, wherein each of the second shift registers comprises:
a second charging circuit, receiving a startup signal to charge a second internal voltage;
a second pull-up circuit, receiving the second internal voltage and a second clock signal for pulling up the corresponding second gate signal according to the second internal voltage and the second clock signal;
a third voltage regulator circuit and a fourth voltage regulator circuit, respectively receiving the second internal voltage for performing voltage regulation to the corresponding second gate signal according to the second internal voltage, wherein the third voltage regulator circuit and the fourth voltage regulator circuit operates alternately; and
a second pull-down circuit, receiving a second pull-down signal for pulling down the corresponding second gate signal according to the second pull-down signal.

9. The display panel as claimed in claim 8, wherein the second pull-up circuit further pulls up a corresponding second driving signal of a plurality of second driving signals according to the second internal voltage and the second clock signal.

10. The display panel as claimed in claim 9, wherein the second pull-down circuit further pulls down the corresponding second driving signal according to the second pull-down signal.

11. The display panel as claimed in claim 8, wherein the falling edge of the corresponding second gate signal substantially matches a falling edge of the second clock signal.

12. The display panel as claimed in claim 1, wherein the first shift registers and the second discharge circuits are disposed at a first side of the pixel array, and the second shift registers and the fist discharge circuits are disposed at a second side of the pixel array opposite to the first side.

13. The display panel as claimed in claim 1, wherein the first gate lines are a plurality of odd-numbered gate lines, and the second gate lines are a plurality of even-numbered gate lines.
